(19) United States
(12) Patent Application Publication
(10) Pub. No.: US 2011/0226323 A1
(43) Pub. Date: Sep. 22, 2011

(54) USE OF THERMALLY STABLE, FLEXIBLE INORGANIC SUBSTRATE FOR PHOTOVOLTAICS

(75) Inventor: Ralph H. Staley, Greenville, DE (US)

(73) Assignee: E.I. DU PONT DE NEMOURS AND COMPANY, Wilmington, DE (US)

(21) Appl. No.: 12/880,197

(22) Filed: Sep. 13, 2010

Related U.S. Application Data
(60) Provisional application No. 61/242,056, filed on Sep. 14, 2009.

(51) Int. Cl. H01L 31/0224; B32B 15/00

(52) U.S. Cl. 136/256; 428/615

(57) ABSTRACT

This invention relates to the use of Li-vermiculite films as flexible inorganic substrates that are light-weight, electrically insulating and thermally stable at 450-700° C. These films are coated with molybdenum and used in the fabrication of thin-film photovoltaic cells. This invention also relates to photovoltaic cells incorporating such flexible inorganic substrates.

### FIELD OF THE INVENTION

This invention relates to flexible inorganic substrates that are light-weight and thermally stable at 450-700° C. that can be used in the fabrication of thin-film photovoltaic cells.

### BACKGROUND

The substrate used for the current generation of thin-film photovoltaic (PV) cells is most commonly glass because it provides a good balance of properties at moderate cost. In particular, glass provides good mechanical support; is thermally and chemically stable to the processes used to deposit various layers of the thin film PV cell onto the substrate; is electrically insulating; and provides excellent barrier properties to protect the water and oxygen-sensitive layers of the PV cell.

Glass substrates also have some disadvantages. They are heavy, prone to breakage, and generally too rigid to be used in potentially more economical roll-to-roll processes. Metal foils can be used as substrates, but have the distinct disadvantage that they are electrically conductive and are also heavy. Organic polymers, such as polyimides, are amenable to use in roll-to-roll processes and can be weight-saving substrates in many applications, but they do not have sufficient thermal and dimensional stability at the high temperatures used to fabricate thin-film photovoltaics to be useful in this application.

Vermiculite is a micaceous mineral that can be swollen by the action of aqueous salts to produce an aqueous dispersion or slurry. Suitable salts include chloride, nitrate or citrate salts of lithium, alkyl-ammonium cations (e.g., n-butyl-ammonium), or cationic amino acids, (e.g., lysine). A preferred salt is lithium citrate. Rinsing the swollen vermiculite with water produces dispersions or slurries of delaminated vermiculite, free of excess salts. [U.S. Pat. No. 4,655,842 and U.S. Pat. No. 4,780,147] In some instances, larger particles are removed from the dispersion or slurry by sedimentation.

Delaminated vermiculite dispersions or slurries can be used to produce vermiculite sheets or films. [U.S. Pat. No. 5,336,348] Lithium-, potassium- and butylammonium-vermiculite films have been produced.

There exists a need for a material such as vermiculite that can serve as a substrate for thin-film photovoltaic cells that is light-weight, electrically insulating, flexible, and dimensionally and thermally stable for thin-film photovoltaic manufacturing.

### SUMMARY OF THE INVENTION

One aspect of the present invention is a multi-layer article comprising:

a) a Li-vermiculite layer; and
b) a molybdenum layer.

Another aspect of this invention is a photovoltaic cell comprising:

c) a layer comprising a photovoltaic material disposed on the molybdenum layer;
d) a transparent conducting oxide layer; and
e) a metal grid top contact layer.

Another aspect of this invention is a photovoltaic cell comprising:

a) a Li-vermiculite layer;
b) a molybdenum layer disposed on the Li-vermiculite layer;
c) a buffer layer;
d) an n-type Si alloy layer;
e) an i-Si alloy layer;
f) a p-type Si alloy layer;
g) a transparent conducting oxide layer; and
f) a metal grid top contact layer.

These and other aspects of the present invention will be apparent to those skilled in the art in view of the present disclosure and the appended claims.

### DETAILED DESCRIPTION

The multi-layer article of this invention can be prepared by first forming a Li-vermiculite layer, followed by deposition of a molybdenum layer on the vermiculite layer. This multi-layer article is useful as a substrate in the manufacture of photovoltaic cells.

### Li-Vermiculite Layer

In an embodiment, the Li-vermiculite layer is formed by draw-down coating of an aqueous Li-vermiculite slurry onto a substrate and then drying the slurry. A substrate may be selected from polymer film, metalized polymer film, coated paper, glass, ceramic, or metal. Other film-forming techniques can also be used, such as sedimentation casting or de-watering methods similar to those used in paper-making.

Suitable Li-vermiculite slurries are 5-20 wt % solids. In some embodiments, the Li-vermiculite slurry is 7.5-18 wt % solids. A suitable aqueous Li-vermiculite slurry is commercially available from W. R. Grace & Co (Cambridge, Mass.) as MicroLite® 963. Different grades are available, wherein the grades differ in concentration and degree of removal of coarse particles. Suitable aqueous Li-vermiculite slurries can also be prepared by refluxing vermiculite in an aqueous lithium chloride solution, followed washing with distilled water, allowing the vermiculite to swell, and then using a shearing macerator to create the degree of fineness of dispersion desired (as described in Example 3 of U.S. Pat. No. 3,325,340 and is herein incorporated by reference). Preparation of suitable Li-vermiculite slurries using lithium citrate or lithium nitrate is described in Example 1 of U.S. Pat No. 4,655,842 which is incorporated by reference, wherein vermiculite is mixed with an aqueous solution of the lithium salt, allowed to stand for 24 hours, and then washed with several portions of distilled water.

Suitable Li-vermiculites contain 0.05, 0.1 or 0.2 to 0.6, 0.8 or 1.0 wt % Li, based on weight % solids.

After the Li-vermiculite coating is formed on the substrate, the slurry is dried. Initial drying is at a temperature of 25-100° C. removing the bulk of the water. The Li-vermiculite film is further dried by heating to about 500° C. Typically, the Li-vermiculite film spontaneously delaminates from the substrate during the initial drying. All subsequent processing is on the free-standing film which forms the Li-vermiculite layer.

The vermiculite film can optionally be run through rollers to compress bubbles formed in the drying process and improve surface smoothness.

### Molybdenum (Mo) Layer

The Mo layer is typically deposited to a thickness of 500-1000 nm by sputtering onto the Li-vermiculite layer.

Preferably, the molybdenum layer is uniform in thickness and pin-hole-free.

### Photovoltaic Cell

Thin-film photovoltaic (PV) cells typically comprise a substrate, a conductive layer, an absorber layer of photovoltaic material, a transparent conducting oxide (TCO) layer, and a metal grid top contact layer. Some embodiments also contain one or more layers selected from buffer layers and interconnect layers.

In the photovoltaic cell of this invention, the substrate is a Li-vermiculite layer, prepared as described above. The conductive layer is a

Mo layer that has been deposited on the Li-vermiculite layer. This provides a flexible inorganic substrate for photovoltaic cells that is light-weight and thermally stable at 450-700° C.

The photovoltaic material is selected from the group consisting of amorphous silicon (a-Si), cadmium telluride (CdTe), copper indium (gallium) di-selenide/sulfide (CIS/CIGS), CuInSe₂, CuInS₂, CuGaSe₂, CuInS₂, CuGaS₂, CuAlSe₂, CuAlS₂, CuAlTe₂, CuGaTe₂, Cu₂ZnSnS₄, Cu₂ZnSnSe₄, and combinations thereof. The layer of photovoltaic material is deposited on the molybdenum layer. In one embodiment, CIGS is applied by co-evaporation of Cu, In and Ga in the presence of Se vapor 600° C., followed by chemical bath deposition of CdS. In another embodiment, CZTS (copper zinc tin sulfide) is applied by printing an ink of precursor particles on the molybdenum layer, followed by annealing at 600° C. The annealing step is followed by chemical bath deposition of CdS.

The TCO layer typically includes mixtures or doped oxides of In₂O₃, SnO₂, ZnO, CdO, and Ga₂O₃. Common examples in PV cells include ITO (In₂O₃ doped with about 9 atomic % Sn) and AZO (ZnO doped with 3-5 atomic % Al). In one embodiment, ZnO is sputter deposited onto the layer of photovoltaic material.

The metal grid top contact layer typically comprises a patterned metal layer, where the metal is selected from the group consisting of copper, silver, gold, nickel, chromium, aluminum and mixtures thereof. In one embodiment, e-beam evaporation is used to deposit Ni/Al grids.

In some embodiments, an anti-reflective coating is deposited on the metal grid top contact layer. Suitable anti-reflective coatings include MgF₂.

The structure of a-Si and nc-Si solar cells is commonly p-i-n for a single cell, wherein “n” refers to n-type Si, “i” refers to insulating Si, and “p” refers to p-type Si. Tandem cells with higher efficiency are produced by stacking this basic cell and optimizing the absorption of the stack.

Thin-film silicon solar cells typically comprise a TCO layer, a p-type Si alloy layer, an i-Si alloy layer, an n-type Si alloy layer, a buffer layer, a metal layer and a substrate. In the thin-film solar cells of this invention, the metal layer is molybdenum and the substrate is a Li-vermiculite layer. Amorphous or nanocrystalline Si is usually an alloy with hydrogen, i.e., a-Si:H or nc-Si:H. Doping n-type or p-type can be accomplished using common dopants used for crystalline Si. Suitable p-type dopants include Group III elements (e.g., B). Suitable n-type dopants include Group V elements (e.g., P). Alloying with Ge or C can also be used to change the optical absorption characteristics and other electrical parameters.

The buffer layer is typically a transparent, electrically insulating dielectric. Suitable materials include CdS, ZnSe, (Zn,Mg)O, In(OH)₃, In₂S₃, In₂Se₃, InZnSeₓ, SnS₂, ZnO, Ga₂O₃, SnO₂, and Zn₂SnO₄.

### Additional Layers

In one embodiment, the photovoltaic cell is laminated to top and bottom sheets using an encapsulant layer. The top and bottom sheets can be glass or polymer films that protect the photovoltaic material from O₂ and H₂O. Ethylene copolymers such as EVA (ethylene vinyl acetate) are suitable encapsulants.

Suitable glass top sheets have high transmission (>80%) throughout the solar spectrum. In some embodiments, the glass sheets have antireflection coatings on at least one side of the glass sheet. Suitable anti-reflective coatings include fluoropolymers.

Suitable polymer sheets can be single layers of a polyester film or a fluoropolymer film, or can be multi-layer laminates comprising at least one layer of a polyester film and at least one layer of a fluoropolymer film bonded together by an adhesive. In some embodiments, at least one polymer sheet further comprises a layer of a metal, metal oxide or non-metal oxide.

Typically, the top sheet is transparent to solar radiation. Leads are attached to the top and bottom conducting layers.

Typically, Mo is the bottom conductive layer and the Ni/Al grid is the top conductive layer. These leads allow connection of the PV cell into a module structure.

### EXAMPLES

### Example 1

### Formation of the Li-vermiculite Layer and Deposition of the Molybdenum Layer

Vermiculite films were fabricated by drawing down a stable dispersion of exfoliated vermiculite in water on cellulose acetate to give a 20 mil thick wet film. The exfoliated vermiculite used was MicroLite® 963 from W. R. Grace & Co., Cambridge, Mass.

The wet film was then dried overnight at room temperature. The room temperature dried vermiculite film was then dried overnight in an oven at 120° C. to remove residual moisture. The oven-dried vermiculite film was then sputter-coated with molybdenum using a magnetron sputter gun in a low pressure argon atmosphere with a 99.95% purity molybdenum target from Angstrom Sciences, Duquesne, Pa. A molybdenum coating of approximately 500 nm was achieved.

### Example 2

### Deposition of the Active Photovoltaic Layer

A layer of an active photovoltaic (PV) material is deposited on the molybdenum layer. CIGS (copper indium gallium diselenide) is applied by co-evaporation of Cu, In and Ga in the presence of Se vapor 600° C., followed by chemical bath deposition of CdS.

### Example 3

### Deposition of Additional Layers

ZnO is sputter-deposited onto the CIGS layer, followed by e-beam evaporation of Ni/Al grids, and physical vacuum deposition of an anti-reflective coating of MgF₂.

What is claimed is:

1. A multi-layer article comprising:
a) a Li-vermiculite layer; and
b) a molybdenum layer.

2. The multi-layer article of claim 1, wherein the Li-vermiculite layer comprises a 0.05 to 1.0 wt % Li, based on weight % solids.

3. The multi-layer article of claim 1, wherein the molybdenum is deposited by sputtering.

4. A photovoltaic cell comprising:
a) a Li-vermiculite layer;
b) a molybdenum layer disposed on the Li-vermiculite layer;
c) a layer comprising a photovoltaic material disposed on the molybdenum layer;
d) a transparent conducting oxide layer; and
e) a metal grid top contact layer.

5. The photovoltaic cell of claim 4, wherein the photovoltaic material is selected from the group consisting of amorphous silicon (a-Si), cadmium telluride (CdTe), copper indium (gallium) di-selenide/sulfide (CIS/GIGS), CuInSe₂, CuInS₂, CuGaSe₂, CuInS₂, CuGaS₂, CuAlSe₂, CuAlS₂, CuAlTe₂, CuGaTe₂, CZTS and combinations thereof.

6. The photovoltaic cell of claim 4, wherein the Li-vermiculite layer comprises a 0.05 to 1.0 wt % Li, based on weight % solids.

7. The photovoltaic cell of claim 4, wherein the transparent conducting oxide is selected from the group consisting of In₂O₃, SnO₂, ZnO, CdO, and Ga₂O₃, ITO, AZO and mixtures thereof.

8. The photovoltaic cell of claim 4, wherein the metal top contact grid comprises a patterned metal layer, wherein the metal is selected from the group consisting of copper, silver, gold, nickel, chromium, aluminum and mixtures thereof.

9. A photovoltaic cell comprising:
a) a Li-vermiculite layer;
b) a molybdenum layer disposed on the Li-vermiculite layer;
c) a buffer layer;
d) an n-type Si alloy layer;
e) an i-Si alloy layer;
f) a p-type Si alloy layer;
g) a transparent conducting oxide layer; and
f) a metal grid top contact layer.
